(19) United States
(12) Patent Application Publication
(10) Pub. No.: US 2025/0374637 A1
(43) Pub. Date: Dec. 4, 2025

(54) SEMICONDUCTOR DEVICE AND METHOD FOR FABRICATING SAME

(71) Applicant: Hangzhou HFC Semiconductor Co., Hangzhou (CN)

(72) Inventors: Mao SUN, Hangzhou (CN); Lixiang GAO, Hangzhou (CN); John H ZHANG, Altamont, NY (US)

(21) Appl. No.: 18/760,406

(22) Filed: Jul. 1, 2024

(30) Foreign Application Priority Data
May 30, 2024 (CN) 202410691860.8

(51) Int. Cl. H01L 29/417; H01L 29/40; H01L 29/66

(52) U.S. Cl. CPC H10D 64/258; H10D 64/01; H10D 64/015; H10D 64/021

(57) ABSTRACT

A semiconductor device and a method for fabricating it are disclosed. The method includes: providing a substrate, on which a gate structure, first spacers on opposite sidewalls of the gate structure, source/drain regions in the substrate on opposite sides of the first spacers and a first interlayer dielectric layer are formed, wherein upper portions of the first spacers proximal to their tops are thinner than the remaining portions of the first spacers; removing a portion of the first interlayer dielectric layer, exposing at least a part of the upper portions of the first spacers; forming second spacers on exposed upper portions of the first spacers; forming a second interlayer dielectric layer, which covers the first interlayer dielectric layer and the gate structure; and forming contact plugs in the second interlayer dielectric layer and the first interlayer dielectric layer, which contact the source/drain regions.

### CROSS-REFERENCE TO RELATED APPLICATION

This application claims the priority of Chinese patent application number 202410691860.8, filed on May 30, 2024 and entitled “SEMICONDUCTOR DEVICE AND METHOD FOR FABRICATING SAME”, the entire contents of which are incorporated herein by reference.

### TECHNICAL FIELD

The present invention relates to the field of semiconductor technology and, in particular, to a semiconductor device and a method for fabricating it.

### BACKGROUND

FIG. 1 schematically illustrates the structure of a semiconductor device. Referring to FIG. 1, the semiconductor device includes a substrate 1, a gate structure 2 formed on the substrate 1 and spacers 3 formed on opposite sidewalls of the gate structure 2. The gate structure 2 includes an oxide layer 21, a high-k (HK) layer 22, a titanium nitride (TiN) layer 23 and a gate 24, which are stacked over the substrate 1. Source or drain regions 4 are formed in the substrate 1 on opposite sides of the gate structure 2, and a first interlayer dielectric layer 5 is formed on the source or drain regions 4 between adjacent gate structures 2. A second interlayer dielectric layer 6 is formed on the first interlayer dielectric layer 5 and the gate structure 2, and contact plugs 7 are formed in the second interlayer dielectric layer 6 and the first interlayer dielectric layer 5 so as to be connected to the source or drain regions 4.

The spacers 3 are usually formed by a process including: forming a spacer material layer, which covers the sidewalls and top of the gate structure 2 and the source or drain regions 4; etching away the spacer material layer on the top of the gate structure 2 and on the source or drain regions 4 so that the spacer material layer remaining on the sidewalls of the gate structure 2 serves as the spacers 3. In the course of etching away the spacer material layer on the top of the gate structure 2 and the source or drain regions 4, the spacer material layer on the sidewalls of the gate structure 2 would be inevitably more or less removed. Consequently, the spacers 3 tend to have thinner upper portions. For example, a portion of the spacer 3 proximal to the second interlayer dielectric layer 6 may comprise a contour curved toward the gate 24. That is, the spacer 15 may have a thickness measured in a direction perpendicular to the spacers, which is smaller at an upper portion than at the lower portion.

As a consequence, after the contact plugs 7 are formed, the gate 24 may be shorted to a source or drain region 4 at a location where the corresponding spacer 3 is thinner, degrading the performance of the semiconductor device.

### SUMMARY OF THE INVENTION

It is an object of the present invention to provide a semiconductor device and a method for fabricating it, in which a gate is prevented from being shorted to a source or drain region, enabling the semiconductor device to have improved performance.

To this end, in a first aspect of the present invention, there is provided a method for fabricating a semiconductor device, comprising:
providing a substrate, wherein at least one gate structure, first spacers on opposite sidewalls of the gate structure, source or drain regions in the substrate on opposite sides of the first spacers and a first interlayer dielectric layer are formed, wherein a thickness of an upper portion of the first spacer proximal to a top thereof is thinner than a thickness of a remaining portion of the first spacer;
removing a portion of the first interlayer dielectric layer, thereby exposing at least a part of the upper portion of each first spacer;
forming a second spacer on the exposed upper portion of each first spacer;
forming a second interlayer dielectric layer, wherein the second interlayer dielectric layer covers the first interlayer dielectric layer and the gate structure; and
forming contact plugs in the second interlayer dielectric layer and the first interlayer dielectric layer, wherein the contact plug contacts the source or drain region.

To the above end, in a second aspect of the present invention, there is also provided a semiconductor device made according to the method as defined above.

In summary, in the semiconductor device and method of the present invention, a thickness of an upper portion of the first spacer proximal to a top thereof is thinner than a thickness of a remaining portion of the first spacer, the first interlayer dielectric layer is partially removed to expose at least a part of the upper portions of the first spacers proximal to their tops, and second spacers are formed on the exposed upper portions of the first spacers. The first and second spacers together make up final spacer for the gate structure. In this way, the upper portions of the first spacers can be thickened to prevent the gate from being shorted to any of the source or drain regions after the contact plugs are formed, enhancing the performance of the resulting semiconductor device.

### BRIEF DESCRIPTION OF THE DRAWINGS

FIG. 1 schematically illustrates the structure of a semiconductor device made according to a conventional method.

FIG. 2 shows a flowchart of a method for fabricating a semiconductor device according to an embodiment of the present invention.

FIGS. 3 to 9 are schematic illustrations of intermediate structures resulting from process steps in a method for fabricating a semiconductor device according to an embodiment of the present invention.

### LIST OF REFERENCE NUMERALS

1—substrate; 2—gate structure; 21—oxide layer; 22—HK layer; 23—TiN layer; 24—gate; 3—spacer; 31—first spacer; 311—upper portion of first spacer; 32—second spacer; 320—second spacer material layer; 4—source or drain region; 5—first interlayer dielectric layer; 6—second interlayer dielectric layer; 7—contact plug.

### DETAILED DESCRIPTION

Objects, advantages and features of the present invention will become more apparent upon reading the following more detailed description of specific embodiments thereof with reference to the accompanying drawings. Note that the figures are provided in a very simplified form not necessarily drawn to exact scale for the only purpose of helping to explain the disclosed embodiments in a more convenient and clearer way.

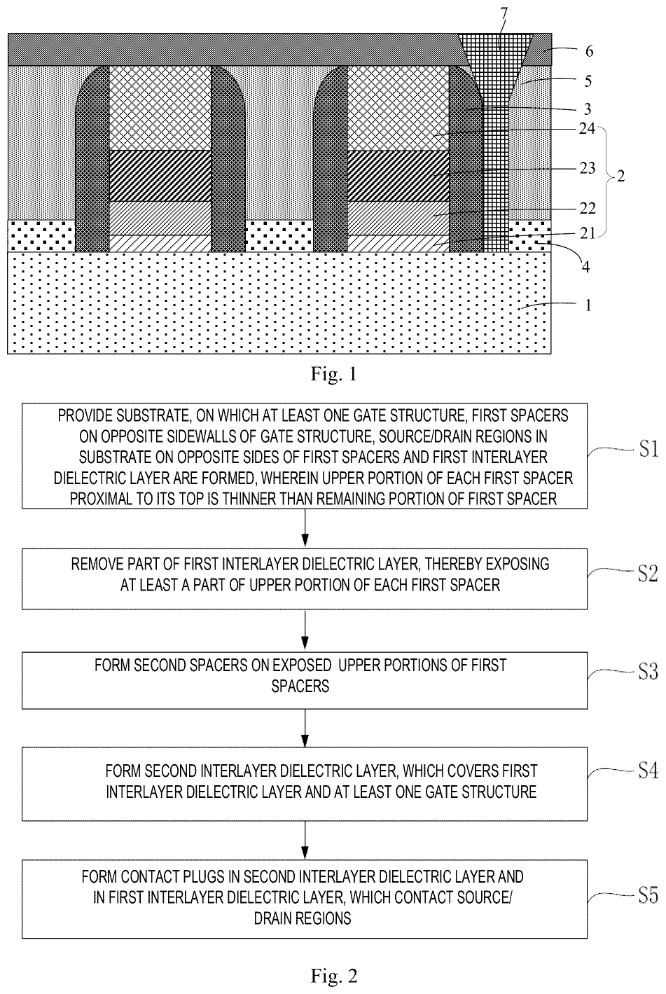

FIG. 2 shows a flowchart of a method for fabricating a semiconductor device according to an embodiment of the present invention. FIGS. 3 to 9 are schematic illustrations of intermediate structures resulting from process steps in a method for fabricating a semiconductor device according to an embodiment of the present invention. Methods for fabricating a semiconductor device according to embodiments of the present invention will be described in detail below with reference to FIGS. 2 and 3 to 9.

In step S1, referring to FIG. 3, a substrate 1 is provided, on which at least a gate structure 2, first spacers 31 on opposite sidewalls of the gate structure 2, source or drain regions 4 in the substrate 1 on opposite sides of the first spacers 31 and a first interlayer dielectric layer 5 are formed. A thickness of an upper portion 311 of each first spacer 31 proximal to the top thereof is thinner than a thickness of the remaining portion of the first spacer 31.

In a non-limiting embodiment of the present invention, the gate structure 2 includes an oxide layer 21, a high-k (HK) layer 22, a titanium nitride (TiN) layer 23 and a gate 24 that are stacked over the substrate 1. The oxide layer 21 may be formed of, for example, silicon oxide. The first spacers 31 may be single-layer spacers or multilayer spacers. For example, each first spacer 31 may include a silicon oxide layer and a silicon nitride layer covering the silicon oxide layer.

The first spacers 31 are formed as a result of an etching process. Therefore, a portion of the first spacer 31 proximal to its top (i.e., distal from the substrate 1) is thinner than the remaining portion of the first spacer 31. As shown in FIG. 3, one side of a top portion of the first spacer 3 may comprise an outer contour (on the side away from the gate structure 2) curved toward the gate structure 2. That is, a thickness of the upper portion of the first spacer 31 gradually decreases towards the top thereof. It would be appreciated that herein the thickness of the first spacer 31 is measured in a direction perpendicular to the first spacer 31, i.e., horizontally as viewed in the orientation of FIG. 3.

Herein, such portions of the first spacers 31 proximal to their corresponding tops, for example, the portions of the first spacers 31 that are curved as shown in FIG. 3, are referred to as an “upper portion 311”. Of course, the upper portions 311 are not limited to being as shown in FIG. 3. Rather, their interfaces with the remaining of the first spacers 31 may be alternatively above or below those shown. That is, the upper portions 311 are arbitrarily determined portions of the first spacers, which are thinner and need improvement.

According to embodiments of the present invention, the upper portions 311 are thinner than the remaining portions of the first spacers 31. The remaining portions of the first spacers 31 may have a constant thickness across their entire length. Of course, the remaining portions may also not have a constant thickness. In the latter case, in the first spacer 31, even a maximum thickness of the upper portion 311 is smaller than a minimum thickness of the remaining portion.

In one embodiment of the present invention, the first interlayer dielectric layer 5 is formed by a high-density plasma chemical vapor deposition (HDPCVD) process. The first interlayer dielectric layer 5 is, for example, a silicon oxide layer.

In step S2, referring to FIG. 4, the first interlayer dielectric layer 5 is partially removed, exposing at least part of the upper portions 311.

In one embodiment of the present invention, a SiCoNi etching process may be used to removal part of the first interlayer dielectric layer 5. That is, the first interlayer dielectric layer 5 is etched back. The top of the processed first interlayer dielectric layer 5 is lower than a top of the gate structure 2, exposing at least part of the upper portions 311. Of course, it is also possible to expose the entire upper portions 311. They may be partially or entirely exposed, depending on the extent of the spacers in need of thickening.

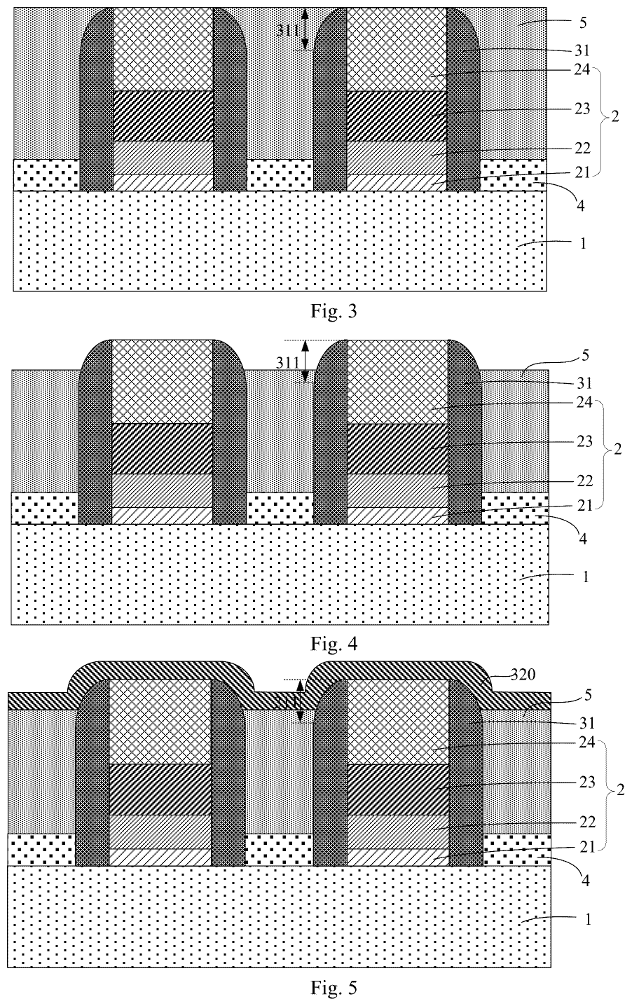

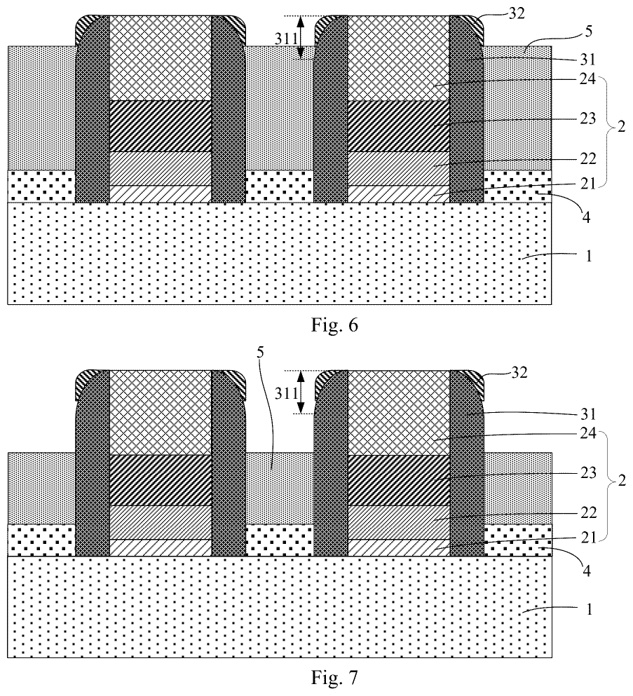

In step S3, referring to FIGS. 5 and 6, second spacers 32 are formed on sidewalls of the upper portions 311.

As an example, referring to FIG. 5, first of all, a second spacer material layer 320 is formed, which covers the top of the gate structure 2, the sidewalls of the upper portions 311 and a surface of the first interlayer dielectric layer 5. Subsequently, the second spacer material layer 320 on the top of the gate structure 2 and the surface of the first interlayer dielectric layer 5 is etched away, while the remaining portion of the second spacer material layer on the sidewalls of the upper portion 311 serves as the second spacers 32, resulting in the structure shown in FIG. 6.

In one embodiment of the present invention, on each side, the sum of thicknesses of the upper portion 311 and the second spacer 32 is smaller than or equal to a maximum thickness of the first spacer 31. Alternatively, on each side, the sum of the thicknesses of the upper portion 311 and the second spacer 32 is smaller than a thickness of the remaining portion of the first spacer 31. This can prevent the resulting final spacers from having an excessively large thickness at portions proximal to their tops, which may adversely affect other components.

In a non-limiting embodiment of the present invention, the second spacer material layer 320, from which the second spacers 32 are made, may contain silicon nitride, and the second spacer material layer 320 is formed using an atomic layer deposition (ALD) process.

In step S4, referring to FIG. 8, a second interlayer dielectric layer 6 is formed, which covers the first interlayer dielectric layer 5 and the gate structure 2.

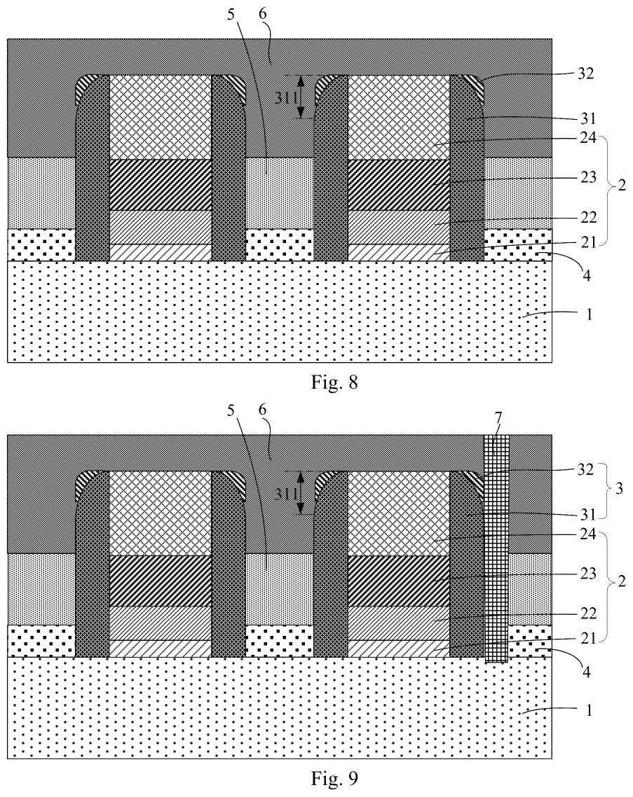

In one embodiment of the present invention, after the second spacers 32 are formed and before the second interlayer dielectric layer 6 is formed, the first interlayer dielectric layer 5 may be thinned, as shown in FIG. 7.

The second interlayer dielectric layer 6 may be then formed so as to cover both the first interlayer dielectric layer 5 and the gate structure 2. That is, the second interlayer dielectric layer 6 fills gaps between adjacent gate structures 2 and covers the gate structures 2. The second interlayer dielectric layer 6 may be formed by a plasma-enhanced chemical vapor deposition (PECVD) process using tetraethylorthosilicate (TEOS) and then planarized to allow the resulting second interlayer dielectric layer 6 to have a flat surface. In one example, the second interlayer dielectric layer 6 may be made of silicon oxide, for example.

In step S5, referring to FIG. 9, contact plugs 7 are formed in the second interlayer dielectric layer 6 and the first interlayer dielectric layer 5 so as to contact the source or drain regions 4.

As an example, the second interlayer dielectric layer 6 and the first interlayer dielectric layer 5 may be successively etched through to form vias exposing the source or drain regions 4, and a conductive material may be then filled in the vias to form the contact plugs 7. The conductive material may be tungsten, for example.

According to embodiments of the present invention, through thickening the thinner portions of the first spacers 31 proximal to their tops (i.e., at least part of the upper portions 311) by forming the second spacers 32 on their sidewalls, the gate 24 can be prevented from being shorted to any of the source or drain regions 4 after the contact plugs 7 are formed, thereby enhancing the performance of the resulting semiconductor device.

The present invention provides a method for fabricating a semiconductor device, which includes: first of all, providing a substrate 1, on which a gate structure 2, first spacers 31 on opposite sidewalls of the gate structure 2, source or drain regions 4 in the substrate 1 on opposite sides of the first spacers 31 and a first interlayer dielectric layer 5 are formed, a thickness of the upper portions 311 of the first spacers 31 proximal to their tops are thinner than a thickness of the remaining portions of the first spacers 31; then removing a portion of the first interlayer dielectric layer 5, exposing at least part of the upper portions 311; and then forming second spacers 32 on exposed sidewalls of the upper portions 311. The first spacers 31 and the second spacers 32 together make up the final spacers 3 for the gate structure 2. Through thickening the upper portions 311, the gate 24 can be prevented from being shorted to any of the source or drain regions 4 after contact plugs 7 are formed, enhancing the performance of the resulting semiconductor device.

The present invention also provides a corresponding semiconductor device obtainable according to the method as defined above. Referring to FIG. 9, the semiconductor device includes:
a substrate 1;
a gate structure 2 formed on the substrate 1;
spacers 3 formed on sidewalls of the gate structure 2, each spacer 3 including a first spacer 31 and a second spacer 32, the first spacer 31 covering a the sidewall of the gate structure 2, a thickness of an upper portion 311 of the first spacer 31 proximal to its top is thinner than a thickness of the remaining portion of the first spacer 31, the second spacer 32 covering a sidewall of the upper portion 311;
source or drain regions 4 in the substrate 1 on opposite sides of the gate structure 2;
a first interlayer dielectric layer 5 formed on the source or drain regions 4 on the opposite sides of the gate structure 2;
a second interlayer dielectric layer 6 covering the first interlayer dielectric layer 5 and the gate structure 2; and
contact plugs 7 extending through the second interlayer dielectric layer 6 and the first interlayer dielectric layer 5 and contacting the source or drain regions 4.

The description presented above is merely that of some preferred embodiments of the present invention and is not intended to limit the scope thereof in any sense. Any and all changes and modifications made by those of ordinary skill in the art based on the above teachings fall within the scope of the invention.

1. A method for fabricating a semiconductor device, comprising
providing a substrate, wherein at least one gate structure, first spacers on opposite sidewalls of the gate structure, source or drain regions in the substrate on opposite sides of the first spacers and a first interlayer dielectric layer are formed on the substrate, wherein a thickness of an upper portion of the first spacer proximal to a top thereof is thinner than a thickness of a remaining portion of the first spacer;
removing a portion of the first interlayer dielectric layer, thereby exposing at least a part of the upper portion of each first spacer;
forming a second spacer on the exposed upper portion of each first spacer;
forming a second interlayer dielectric layer, wherein the second interlayer dielectric layer covers the first interlayer dielectric layer and the at least one gate structure; and
forming contact plugs in the second interlayer dielectric layer and the first interlayer dielectric layer, wherein the contact plug contacts the source or drain region.

2. The method according to claim 1, wherein a sum of a thickness of the upper portion of the first spacer and a thickness of a corresponding second spacer is smaller than or equal to a maximum thickness of the first spacer.

3. The method according to claim 1, wherein forming the second spacer on the exposed upper portion of each first spacer comprises:
forming a second spacer material layer, wherein the second spacer material layer covers a top of each gate structure, the upper portion of each first spacer and a surface of the first interlayer dielectric layer; and
etching away the second spacer material layer formed on the top of the at least one gate structure and the surface of the first interlayer dielectric layer, with the second spacer material layer remaining on the upper portion of each first spacer serving as the second spacers.

4. The method according to claim 3, wherein the second spacer material layer is formed using an atomic layer deposition (ALD) process.

5. The method according to claim 4, wherein the second spacer is made of a material containing silicon nitride.

6. The method according to claim 1, further comprising, after the second spacers are formed and before the second interlayer dielectric layer is formed, removing a portion of the first interlayer dielectric layer.

7. The method according to claim 1, wherein forming the first interlayer dielectric layer by using a high-density plasma chemical vapor deposition (HDPCVD) process.

8. The method according to claim 1, wherein forming the second interlayer dielectric layer by a plasma-enhanced chemical vapor deposition (PECVD) process using tetraethylorthosilicate (TEOS).

9. The method according to claim 1, wherein the gate structure comprises an oxide layer, a high-k (HK) layer, a titanium nitride layer and a gate that are stacked over the substrate.

10. A semiconductor device fabricated according to the method according claim 1, wherein the semiconductor device comprises:
a substrate;
at least one gate structure formed on the substrate;
spacers formed on sidewalls of the at least one gate structure, wherein the spacer includes a first spacer and a second spacer, wherein the first spacer covers a sidewall of the gate structure, wherein a thickness of an upper portion of the first spacer proximal to a top thereof is thinner than a thickness of a remaining portion of a corresponding first spacer, wherein the second spacer covers a sidewall of the upper portion;
source or drain regions formed in the substrate on opposite sides of the gate structure;
a first interlayer dielectric layer formed on the source or drain regions located on the opposite sides of the gate structure;
a second interlayer dielectric layer covering the first interlayer dielectric layer and the at least one gate structure; and
contact plugs extending through the second interlayer dielectric layer and the first interlayer dielectric layer, thereby contacting the source or drain regions.

11. The semiconductor device of claim 10, wherein a sum of a thickness of the upper portion of the first spacer and a thickness of a corresponding second spacer is smaller than or equal to a maximum thickness of the first spacer.

12. The semiconductor device of claim 10, wherein the second spacer is made of a material containing silicon nitride.

13. The semiconductor device of claim 10, wherein the first interlayer dielectric layer is formed using a high-density plasma chemical vapor deposition (HDPCVD) process.

14. The semiconductor device of claim 10, wherein the second interlayer dielectric layer is formed by a plasma-enhanced chemical vapor deposition (PECVD) process using tetraethylorthosilicate (TEOS).

15. The semiconductor device of claim 10, wherein the gate structure comprises an oxide layer, a high-k (HK) layer, a titanium nitride layer and a gate that are stacked over the substrate.
